(19) United States
(12) Patent Application Publication
(10) Pub. No.: US 2022/0187400 A1
(43) Pub. Date: Jun. 16, 2022

(54) MAGNETIC RESONANCE IMAGING APPARATUS AND IMAGE GENERATION METHOD

(71) Applicant: CANON MEDICAL SYSTEMS CORPORATION, Otawara-shi (JP)

(72) Inventors: Hideaki KUTSUNA, Kawasaki (JP); Hidenori TAKESHIMA, Kawasaki (JP)

(73) Assignee: CANON MEDICAL SYSTEMS CORPORATION, Otawara-shi (JP)

(21) Appl. No.: 17/520,003

(22) Filed: Nov. 5, 2021

(30) Foreign Application Priority Data
Dec. 10, 2020 (JP) 2020-204787

(51) Int. Cl. G01R 33/54; G01R 33/483; G01R 33/48

(52) U.S. Cl. CPC G01R 33/543; G01R 33/4824; G01R 33/483

(57) ABSTRACT

An MRI apparatus according to the present embodiment acquires a plurality of MR signals corresponding to read-out directions including a first read-out direction and a second read-out direction intersecting the first read-out direction, and. The MRI apparatus includes processing circuitry and a low-pass filter. The processing circuitry specifies a signal area relating to generation of the MR signals in a subject. The processing circuitry sets a cutoff frequency defining a passband for the MR signals based on the signal area. The low-pass filter filters the MR signals acquired by scanning performed on the subject in the read-out directions using the cutoff frequency. The processing circuitry generates an MR image based on MR data generated by A/D conversion performed on the MR signals output from the low-pass filter.

### CROSS-REFERENCE TO RELATED APPLICATIONS

This application is based upon and claims the benefit of priority from Japanese Patent Application No. 2020-204787, filed on Dec. 10, 2020; the entire contents of which are incorporated herein by reference.

### FIELD

Embodiments described herein relate generally to a magnetic resonance imaging apparatus and an image generation method.

### BACKGROUND

Magnetic resonance imaging (hereinafter, referred to as MRI) apparatuses have common problems in imaging, including aliasing in an image due to insufficiency of a sampling rate for received magnetic resonance (hereinafter, referred to as MR) signals (that is, insufficiency of a field of view corresponding to the reciprocal of a sampling interval). To address this problem, there have been developed some technologies, such as setting a low-pass filter with a sampling rate and oversampling the MR signals.

If the low-pass filter according to the technologies is used for the MR signals in scanning performed in varying read-out directions, such as radial scanning, the number of signals cut off by the low-pass filter varies depending on the read-out directions. This impairs the consistency of MR data disposed in a k-space between the different read-out directions. As a result, noise, such as streaky artifacts called streaks, occurs in an MR image generated by scanning performed in varying read-out directions, thereby deteriorating image quality.

### BRIEF DESCRIPTION OF THE DRAWINGS

FIG. 1 is a block diagram of an example of a magnetic resonance imaging apparatus according to a first embodiment;

FIG. 2 is a diagram of an exemplary configuration of reception circuitry according to the first embodiment;

FIG. 3 is a diagram of an example of trajectories in a k-space relating to read-out of MR signals in main scanning according to the first embodiment;

FIG. 4 is a flowchart of an example of an image generation process according to the first embodiment;

FIG. 5 is a diagram of an example of signal areas in a locator image according to the first embodiment;

FIG. 6 is a diagram of an example of a read-out direction and sampling points in a k-space and signal areas, various FOVs, a reconstruction region, stopbands, and cut-off positions corresponding to cutoff frequencies in an image space according to the first embodiment;

FIG. 7 is a diagram of an example of the read-out direction and the sampling points in the k-space and the signal areas, various FOVs, the reconstruction region, the stopbands, and the cut-off positions corresponding to the cutoff frequencies in the image space according to the first embodiment;

FIG. 8 is a diagram of an example of the read-out direction and the sampling points in the k-space and the signal areas, various FOVs, the reconstruction region, the stopbands, and the cut-off positions corresponding to the cutoff frequencies in the image space according to the first embodiment;

FIG. 9 is a diagram for explaining advantageous effects according to the first embodiment;

FIG. 10 is a block diagram of an example of the magnetic resonance imaging apparatus according to a second embodiment;

FIG. 11 is a diagram of an example of the read-out direction and the sampling points in the k-space and the signal areas, various FOVs, the reconstruction region, the stopbands, and the cut-off positions corresponding to the cutoff frequencies in the image space according to the second embodiment; and

FIG. 12 is a diagram of an example of the read-out direction and the sampling points in the k-space and the signal areas, various FOVs, the reconstruction region, the stopbands, and the cut-off positions corresponding to the cutoff frequencies in the image space according to the second embodiment.

### DETAILED DESCRIPTION

Exemplary embodiments of a magnetic resonance imaging (hereinafter, referred to as MRI) apparatus and an image generation method are described below in greater detail with reference to the accompanying drawings. Technical ideas according to the embodiments may be applied to MRI apparatuses, such as positron emission tomography (PET)-MRI apparatuses and single photon emission computed tomography (SPECT)-MRI apparatuses, and various complex modalities.

An MRI apparatus according to the present embodiment acquires a plurality of MR signals corresponding to read-out directions including a first read-out direction and a second read-out direction intersecting the first read-out direction, and. The MRI apparatus includes processing circuitry and a low-pass filter. The processing circuitry specifies a signal area relating to generation of the MR signals in a subject. The processing circuitry sets a cutoff frequency defining a passband for the MR signals based on the signal area. The low-pass filter filters the MR signals acquired by scanning performed on the subject in the read-out directions using the cutoff frequency. The processing circuitry generates an MR image based on MR data generated by A/D conversion performed on the MR signals output from the low-pass filter.

### First Embodiment

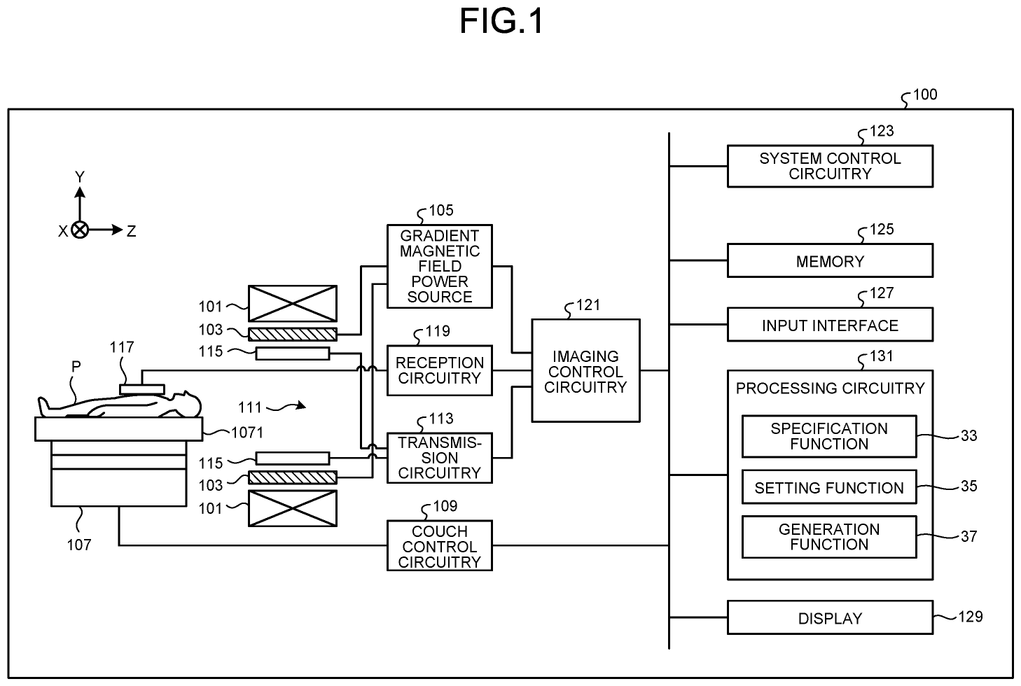

FIG. 1 is a diagram of an example of an MRI apparatus 100 according to the present embodiment. As illustrated in FIG. 1, the MRI apparatus 100 includes a static magnetic field magnet 101, a gradient coil 103, a gradient magnetic field power source 105, a couch 107, couch control circuitry 109, transmission circuitry 113, a transmission coil 115, a reception coil 117, reception circuitry 119, imaging control circuitry (imaging controller) 121, system control circuitry (system controller) 123, a memory 125, an input interface 127, a display 129, and processing circuitry 131.

The static magnetic field magnet 101 is a hollow magnet having a substantially tubular shape. The static magnetic field magnet 101 generates a substantially uniform static magnetic field in the internal space. The static magnetic field magnet 101 is a superconducting magnet, for example.

The gradient coil 103 is a hollow coil having a substantially tubular shape and is disposed on the inner surface of a tubular cooling container. The gradient coil 103 independently receives an electric current from the gradient magnetic field power source 105 and generates a gradient magnetic field having magnetic field intensity that changes along X-, Y-, and Z-axes orthogonal to one another. The gradient magnetic field in the X-, Y-, and Z-axes generated by the gradient coil 103 forms a slice selection gradient magnetic field, a phase encoding gradient magnetic field, and a frequency encoding gradient magnetic field, for example. The slice selection gradient magnetic field is used to optionally determine an imaging section. The phase encoding gradient magnetic field is used to change the phase of magnetic resonance signals (hereinafter, referred to as MR signals) depending on the spatial position. The frequency encoding gradient magnetic field is used to change the frequency of MR signals depending on the spatial position.

The gradient magnetic field power source 105 is a power supply device that supplies an electric current to the gradient coil 103 under the control of the imaging control circuitry 121.

The couch 107 is a device including a couchtop 1071 on which a subject P is placed. The couch 107 inserts the couchtop 1071 with the subject P placed thereon into a bore 111 under the control of the couch control circuitry 109.

The couch control circuitry 109 controls the couch 107. The couch control circuitry 109 drives the couch 107 based on an instruction given by an operator through an input/output interface 17, thereby moving the couchtop 1071 in the longitudinal and vertical directions and the horizontal direction in some cases.

The transmission circuitry 113 supplies high frequency pulses modulated at the Larmor frequency to the transmission coil 115 under the control of the imaging control circuitry 121. The transmission circuitry 113 includes an oscillating unit, a phase selecting unit, a frequency converting unit, an amplitude modulating unit, and an RF amplifier, for example. The oscillating unit generates RF pulses at a resonance frequency unique to a target atomic nucleus in the static magnetic field. The phase selecting unit selects the phase of the RF pulses generated by the oscillating unit. The frequency converting unit converts the frequency of the RF pulses output from the phase selecting unit. The amplitude modulating unit modulates the amplitude of the RF pulses output from the frequency converting unit based on the sinc function, for example. The RF amplifier amplifies the RF pulses output from the amplitude modulating unit and supplies them to the transmission coil 115.

The transmission coil 115 is a radio frequency (RF) coil disposed on the inner side of the gradient coil 103. The transmission coil 115 generates RF pulses corresponding to a high frequency magnetic field due to output from the transmission circuitry 113.

The reception coil 117 is an RF coil disposed on the inner side of the gradient coil 103. The reception coil 117 receives MR signals output from the subject P by the high frequency magnetic field. The reception coil 117 outputs the received MR signals to the reception circuitry 119. The reception coil 117 is a coil array including one or more coil elements, typically, a plurality of coil elements, for example. To make a specific explanation, the following describes the reception coil 117 as a coil array including a plurality of coil elements.

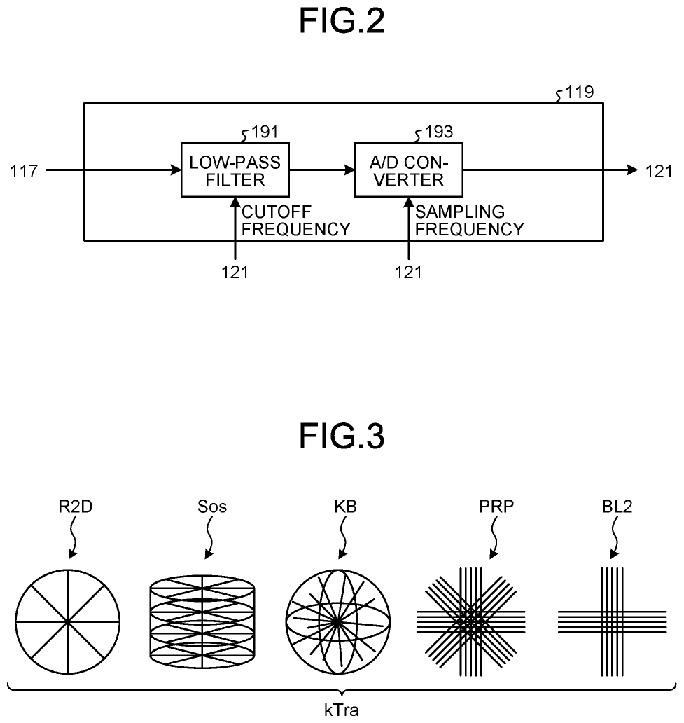

The reception coil 117 may be composed of one coil element. While the transmission coil 115 and the reception coil 117 are illustrated as different RF coils in FIG. 2, they may be provided as an integrated transmission/reception coil. The transmission/reception coil is a local transmission/reception RF coil, such as a head coil, corresponding to an imaging region of the subject P.

The reception circuitry 119 generates digital MR signals (hereinafter, referred to as MR data) based on the MR signals output from the reception coil 117 under the control of the imaging control circuitry 121. Specifically, the reception circuitry 119 performs signal processing, such as wave detection and filtering, on the MR signals output from the reception coil 117. Subsequently, the reception circuitry 119 performs analog to digital (A/D) conversion (hereinafter, referred to as A/D conversion) on the data resulting from the signal processing to generate MR data. The reception circuitry 119 outputs the generated MR data to the imaging control circuitry 121. The MR data, for example, is generated for each coil element and is output to the imaging control circuitry 121 with a tag for identifying the coil element.

FIG. 2 is a diagram of an example of the reception circuitry 119. The reception circuitry 119 includes a low-pass filter 191 and an A/D converter 193. The reception circuitry 119 may also include various kinds of circuitry, such as a wave detector that performs the signal processing, besides the low-pass filter 191 and the A/D converter 193.

The low-pass filter 191 receives a cutoff (cut-off) frequency set by a setting function 35 via the imaging control circuitry 121. In other words, the passband of the low-pass filter 191 is set by the setting function 35. The cutoff frequency may be directly transmitted from the processing circuitry 131 to the low-pass filter 191. The low-pass filter 191 uses the received cutoff frequency to filter the MR signals.

The A/D converter 193 receives a sampling frequency set by the setting function 35 via the imaging control circuitry 121. In other words, the sampling interval of the A/D converter 193 is set by the setting function 35. The A/D converter 193 samples the MR signals having passed through the low-pass filter 191 at a sampling timing corresponding to the sampling frequency. As a result, the A/D converter 193 generates MR data.

The imaging control circuitry 121 controls the gradient magnetic field power source 105, the transmission circuitry 113, the reception circuitry 119, and other components according to an imaging protocol output from processing circuitry 131 and performs imaging on the subject P. The imaging protocol has a pulse sequence corresponding to the type of an examination. The imaging protocol defines the magnitude of an electric current supplied to the gradient coil 103 by the gradient magnetic field power source 105, the timing at which the gradient magnetic field power source 105 supplies the electric current to the gradient coil 103, the magnitude and the time width of high frequency pulses supplied to the transmission coil 115 by the transmission circuitry 113, the timing at which the transmission coil 115 supplies the high frequency pulses to the transmission coil 115, and the timing at which the reception coil 117 receives MR signals, for example. When the imaging control circuitry 121 images the subject P by driving the gradient magnetic field power source 105, the transmission circuitry 113, the reception circuitry 119, and other components and receives MR data from the reception circuitry 119, it transfers the received MR data to the processing circuitry 131.

The imaging control circuitry 121 executes the pulse sequence for imaging, thereby acquiring MR data. Imaging performed by the present embodiment corresponds to scanning for acquiring a plurality of MR signals corresponding to a plurality of read-out directions including a first read-out direction and a second read-out direction intersecting the first read-out direction. Consequently, the MRI apparatus 100 acquires a plurality of MR signals corresponding to a plurality of read-out directions including the first read-out direction and the second read-out direction intersecting the first read-out direction.

FIG. 3 is a diagram of an example of trajectories kTra in a k-space relating to read-out of MR signals in main scanning. Examples of the main scanning include, but are not limited to, two-dimensional radial acquisition R2D, three-dimensional radial acquisition (stack-of-stars) Sos, koosh-ball (KB), periodically rotated overlapping parallel lines with enhanced reconstruction (PROPELLER) acquisition PRP, acquisition BL2 with two blades, etc., as illustrated in FIG. 3.

To make a specific explanation, the following describes the main scanning as two-dimensional radial acquisition R2D. The two-dimensional radial acquisition R2D is hereinafter simply referred to as radial acquisition. The number of times of read-out in radial acquisition performed on the subject P as the main scanning, that is, the number of trajectories kTra in the read-out directions are set in advance before the main scanning.

The imaging control circuitry 121 may acquire MR data (hereinafter, referred to as coil sensitivity data) relating to generation of an image (hereinafter, referred to as a coil sensitivity map) indicating the distribution of sensitivity of the reception coil 117 used to image the subject P by a desired imaging method. The coil sensitivity map is expressed by a complex number of data. The coil sensitivity data is acquired by the imaging control circuitry 121 in pre-scanning including locator scanning performed before the radial acquisition R2D performed as the main scanning, for example. The imaging control circuitry 121 is provided as a processor, for example.

The term “processor” means circuitry, such as a CPU, a graphics processing unit (GPU), an application specific integrated circuit (ASIC), a programmable logic device (e.g., a simple programmable logic device (SPLD)), a complex programmable logic device (CPLD), and a field programmable gate array (FPGA).

The system control circuitry 123 includes a processor and memories, such as a read-only memory (ROM) and a random access memory (RAM), which are not illustrated as hardware resources, and controls the MRI apparatus 100 by a system control function. Specifically, the system control circuitry 123 reads out a system control program stored in the memory and loads it on the memory. The system control circuitry 123 controls the circuitry of the MRI apparatus 100 according to the loaded system control program.

The system control circuitry 123, for example, reads out the imaging protocol from the memory 125 based on imaging conditions input by the operator through the input interface 127. The system control circuitry 123 transmits the imaging protocol to the imaging control circuitry 121 and controls imaging on the subject P. The system control circuitry 123 is provided as a processor, for example. The system control circuitry 123 may be incorporated in the processing circuitry 131. In this case, the processing circuitry 131 carries out the system control function and functions as an alternative to the system control circuitry 123. The processor serving as the system control circuitry 123 is not explained herein because it has the same configuration as that described above.

The memory 125 stores therein various computer programs relating to the system control function carried out by the system control circuitry 123, various imaging protocols, and imaging conditions including a plurality of imaging parameters defining the imaging protocols, for example. The memory 125 also stores therein a specification function 33, the setting function 35, and a generation function 37 implemented by the processing circuitry 131 as computer-executable programs.

The memory 125 stores therein MR images generated by the generation function 37 and pre-scanning images generated by pre-scanning, such as locator scanning. The pre-scanning images include a positioning image (also referred to as a locator image) for setting a field of view (hereinafter, referred to as an FOV) in the main scanning and a coil sensitivity map used to reconstruct an MR image in the main scanning, for example. In other words, the memory 125 stores therein a plurality of coil sensitivity maps corresponding to the respective coil elements. The memory 125 also stores therein an FOV set in a locator image serving as a pre-scanning image.

The memory 125 stores therein a sampling frequency (a sampling rate or a sampling interval) used by the A/D converter 193 in the main scanning performed after the pre-scanning. The memory 125 also stores therein a cutoff frequency used by the low-pass filter 191 in the main scanning. The memory 125 also stores therein MR data relating to the main scanning and an algorithm for reconstructing an MR image based on the MR data.

The memory 125 may store therein various kinds of data received via a communication interface, which is not illustrated. The memory 125, for example, stores therein information (e.g., an imaging target region and a purpose of an examination) on an examination order for the subject P received from an information processing system, such as a radiology information system (RIS), in a medical institution.

The memory 125 is provided as a semiconductor memory element, such as a ROM, a RAM, and a flash memory, a hard disk drive (HDD), a solid state drive (SSD), or an optical disc, for example. The memory 125 may be provided as a drive device or the like that reads and writes various kinds of information from and to a portable storage medium, such as a compact disc (CD)-ROM drive, a digital versatile disc (DVD) drive, and a flash memory.

The input interface 127 receives various instructions (e.g., a power-on instruction) and information from the operator. The input interface 127 is provided as a trackball, a switch button, a mouse, a keyboard, a touch pad on which the operator performs an input operation by touching an operating screen, a touch screen that integrates a display screen and a touch pad, contactless input circuitry provided with an optical sensor, or voice input circuitry, for example. The input interface 127 is coupled to the processing circuitry 131. The input interface 127 converts an input operation received from the operator into electrical signals and outputs them to the processing circuitry 131. The input interface 127 in the present specification is not limited to a component including physical operating parts, such as a mouse and a keyboard. The input interface 127 may be processing circuitry that receives electrical signals corresponding to an input operation from an external input device provided separately from the MRI apparatus 100 and outputs the electrical signals to the control circuitry, for example.

The input interface 127 inputs an FOV to a pre-scanning image displayed on the display 129 based on an instruction given by a user. Specifically, the input interface 127 inputs an FOV based on an instruction for setting a range by the user in a locator image displayed on the display 129. The input interface 127 inputs various imaging parameters relating to the main scanning according to an instruction giving by the user based on the examination order.

The display 129 displays various graphical user interfaces (GUI), an MR image generated by the processing circuitry 131, a pre-scanning image, such as a locator image, and other images under the control of the processing circuitry 131 or the system control circuitry 123. The display 129 also displays an imaging parameter image relating to the main scanning and the pre-scanning and various kinds of information relating to image processing, for example. The display 129 is provided as a display device, such as a CRT display, a liquid crystal display, an organic EL display, an LED display, a plasma display, or other desired displays or monitors known in the present technical field.

The processing circuitry 131 is provided as the processor described above, for example. The processing circuitry 131 includes the specification function 33, the setting function 35, and the generation function 37, for example. The processing circuitry 131 that implements the specification function 33, the setting function 35, and the generation function 37 corresponds to a specifying unit, a setting unit, and a generating unit. Various functions, such as the specification function 33, the setting function 35, and the generation function 37, are stored in the memory 125 as computer-executable programs. The processing circuitry 131, for example, reads out a computer program from the memory 125 and executes it, thereby implementing the function corresponding to the computer program. In other words, the processing circuitry 131 that has read out the computer programs has various functions, such as the specification function 33, the setting function 35, and the generation function 37.

While the “processor” reads out the computer programs corresponding to the respective functions from the memory 125 and executes them in the description above, the embodiment is not limited thereto. If the processor is a CPU, for example, the processor reads out a computer program stored in the memory 125 and executes it, thereby implementing the corresponding function. If the processor is an ASIC, the computer program is not stored in the memory 125, and the function is directly incorporated in the circuitry of the processor as a logic circuit. The processors according to the present embodiment do not necessarily each provided as single circuitry. Alternatively, a plurality of independent circuitry may be combined to serve as one processor and implement the functions. While the single storage circuitry stores therein the computer programs corresponding to the respective processing functions in the description above, the embodiment is not limited thereto. A plurality of storage circuitry may be dispersed and disposed, and the processing circuitry 131 may read out a computer program from the corresponding storage circuitry.

The specification function 33 of the processing circuitry 131 specifies a signal area relating to generation of MR signals in the subject P. The signal area corresponds to an area in which protons, such as water molecules, are present in an imaging space. The specification function 33 specifies an area in which the subject P is imaged (hereinafter, referred to as an imaging area) in a pre-scanning image as the signal area. Specifically, the specification function 33 specifies the imaging area corresponding to the area of the subject P by detecting an image of the subject P in the pre-scanning image or specifying the area in the pre-scanning image by the user.

The specification function 33, for example, performs area detection for detecting an imaging area on the pre-scanning image, thereby specifying the signal area. The area detection is not explained herein because it can be performed by appropriately performing existing image recognition, such as edge detection, on the pre-scanning image. The specification function 33 may specify the signal area based on an area specification instruction given by the user through the input interface 127 in the pre-scanning image displayed on the display 129. The area specification instruction is an input instruction indicating a figure (e.g., a quadrilateral, such as a rectangle, or an ellipse) for specifying a range in the pre-scanning image, for example.

The setting function 35 of the processing circuitry 131 sets a cutoff frequency defining a passband for MR signals based on the specified signal area. Specifically, the setting function 35 sets the cutoff frequency further using an FOV in the main scanning of scanning the subject P in a plurality of read-out directions and the intensity of the gradient magnetic field in the main scanning. The setting function 35 may set the cutoff frequency so as to include the signal area relating to generation of MR signals. The setting function 35 may set cutoff frequencies for the respective read-out directions based on the specified signal area. The processing contents of setting the cutoff frequency by the setting function 35 will be described later in greater detail in the description of processing of imaging the subject P by the main scanning and generating an MR image (hereinafter, referred to as image generation process).

The generation function 37 of the processing circuitry 131 acquires MR data (hereinafter, referred to as pre-scanning data) generated by pre-scanning performed on the subject P from the reception circuitry 119 and disposes it in a k-space. The generation function 37 generates a pre-scanning image based on the pre-scanning data disposed in the k-space. The generation function 37 stores the generated pre-scanning image in the memory 125.

The generation function 37, for example, acquires MR data generated by scanning for generating a locator image from the reception circuitry 119 and disposes it in a k-space. The generation function 37 generates (reconstructs) a locator image based on the MR data disposed in the k-space. The generation function 37 acquires coil sensitivity data generated by scanning for generating a coil sensitivity map from the reception circuitry 119 and disposes it in a k-space. The generation function 37 generates (reconstructs) a coil sensitivity map based on the coil sensitivity data disposed in the k-space. Generating the locator image, the coil sensitivity map, and other data is not explained herein because it can be performed using an existing reconstruction method.

The generation function 37 of the processing circuitry 131 generates an MR image (hereinafter, referred to as a main scanning image) based on MR data generated by A/D conversion performed on MR signals output from the low-pass filter 191 in the main scanning. The generation function 37, for example, generates the main scanning image by sensitivity encoding (hereinafter, referred to as SENSE) using the MR data generated by the main scanning and the coil sensitivity map. The method for generating the main scanning image is not limited to SENSE and may be compressed sensing (CS) or a reconstruction method for super resolution, for example. The generation function 37 stores the main scanning image in the memory 125. The processing contents of generating the main scanning image will be described later in greater detail in the description of the image generation process.

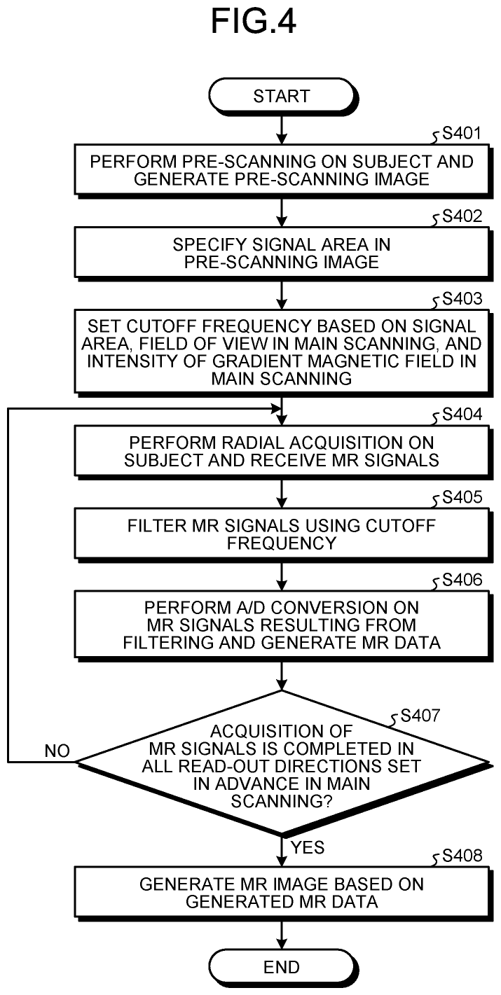

The following describes the image generation process performed by the MRI apparatus 100 according to the present embodiment having the configuration described above with reference to FIGS. 4 to 9. FIG. 4 is a flowchart of an example of the image generation process.

Image Generation Process

Step S401 The imaging control circuitry 121 performs pre-scanning on the subject P. The generation function 37 of the processing circuitry 131 generates a pre-scanning image based on pre-scanning data. The generation function 37 stores the generated pre-scanning image, such as a locator image and a coil sensitivity image, in the memory 125. The system control circuitry 123 displays the locator image on the display 129.

The input interface 127 inputs an FOV (hereinafter, referred to as a user FOV) in the locator image based on an instruction given by the user. The user FOV input by the user is stored in the memory 125. The setting function 35 sets a sampling frequency based on the user FOV and outputs the set sampling frequency to the A/D converter 193. The setting function 35, for example, multiplies the reciprocal of the size of the user FOV by a constant, thereby setting a sampling frequency corresponding to oversampling, that is, a sampling interval.

Step S402

The specification function 33 of the processing circuitry 131 performs area detection on the locator image to specify a signal area in the locator image. The method for specifying the signal area in the locator image is not limited to area detection. The signal area may be specified based on an instruction given by the user through the input interface 127, for example.

The system control circuitry 123 displays the pre-scanning image on the display 129. In other words, the display 129 displays the locator image under the control of the system control circuitry 123. The input interface 127 inputs an input instruction for specifying the signal area to the displayed locator image by an operation performed by the user. As a result, the specification function 33 of the processing circuitry 131 specifies the signal area.

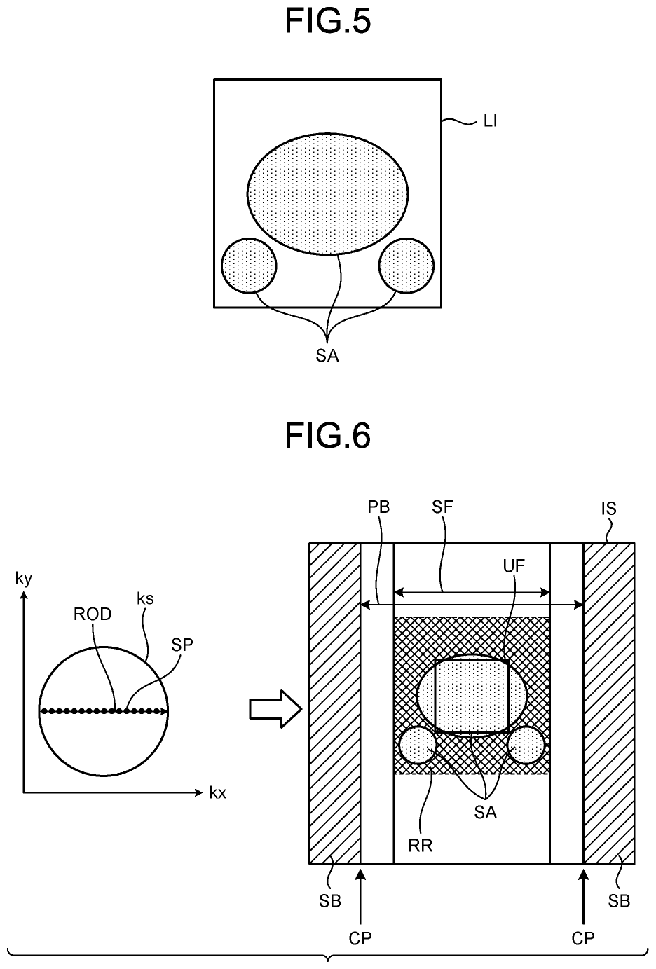

FIG. 5 is a diagram of an example of signal areas SA in a locator image LI. If the signal area SA is specified through the input interface 127, a figure (e.g., a quadrilateral, such as a rectangle, or an ellipse) for specifying a range in the locator image LI is input based on an instruction given by the user.

Step S403

The setting function 35 of the processing circuitry 131 sets a cutoff frequency of the low-pass filter 191 to be applied to MR signals received in the main scanning. Specifically, the setting function 35 sets a tentative cutoff frequency (hereinafter, referred to as a tentative cut-off frequency) based on the intensity of the gradient magnetic field in the main scanning and the user FOV. The setting function 35, for example, sets the tentative cut-off frequency using the band of the low-pass filter 191 in the following expression:

User FOV [cm]=(2×Band [Hz] of Low-Pass Filter)/Intensity of Read-Out Gradient Magnetic Field [Hz/cm]

In the expression, the intensity of the read-out gradient magnetic field corresponds to the intensity of the gradient magnetic field in the main scanning.

Subsequently, the setting function 35 transforms the tentative cut-off frequency in an image space and compares it with the specified signal area. In the following description, the tentative cut-off frequency transformed in the image space is referred to as a tentative cut-off position. The setting function 35 specifies the position farthest from the tentative cut-off position (hereinafter, referred to as the farthest position) in the signal area protruding from the passband of the low-pass filter 191 defined by the tentative cut-off position in a plurality of read-out positions in the main scanning. The setting function 35 sets a frequency corresponding to the farthest position (hereinafter, referred to as the farthest frequency) as the cutoff frequency. The setting function 35 may set a frequency obtained by adding a predetermined margin frequency to the farthest frequency as the cutoff frequency.

In other words, the setting function 35 sets the cutoff frequency so as to include the signal area relating to generation of MR signals. The setting function 35, for example, sets the cutoff frequencies for the respective read-out directions so as to include the signal area relating to generation of MR signals. Setting the cutoff frequency corresponds to expanding the passband for MR signals by the tentative cut-off frequency, for example. Setting the cutoff frequency so as to include the signal area relating to generation of MR signals may be performed based on an instruction given by the user through the input interface 127. As a result, the number of MR signals received in the main scanning is uniform regardless of the read-out directions in the main scanning. In other words, the setting function 35 sets the cutoff frequency such that the number of MR signals is uniform regardless of the read-out directions. The setting function 35 outputs the set cutoff frequency to the low-pass filter 191.

Step S404

The imaging control circuitry 121 performs radial acquisition as the main scanning on the subject P. Specifically, the imaging control circuitry 121 performs imaging along one read-out direction in the main scanning. As a result, the reception coil 117 receives MR signals in the read-out direction. The MR signals received by the reception coil 117 are output to the reception circuitry 119. At this time, the MR signals are detected by a wave detector.

Step S405

The low-pass filter 191 filters the MR signals resulting from wave detection using the set cutoff frequency. Filtering the MR signals by the low-pass filter 191 reduces the number of unnecessary signals outside the user FOV. As a result, the S/N of the MR signals and the like is improved. The MR signals resulting from filtering are output to the A/D converter 193.

Step S406

The A/D converter 193 samples the MR signals output from the low-pass filter 191 using the set sampling frequency. As a result, the A/D converter 193 generates MR data. In other words, the A/D converter 193 performs A/D conversion on the MR signals having passed through the low-pass filter 191 at the sampling frequency, thereby generating MR data. The MR data is stored in the memory 125 via the imaging control circuitry 121.

Step S407

If acquisition of the MR signals is completed in all the read-out directions (corresponding to the total number of trajectories kTra in the read-out directions) set in advance in the main scanning (Yes at Step S407), the processing at Step S408 is performed. If acquisition of the MR signals is not completed in all the read-out directions in the main scanning (No at Step S407), the processing from Step S404 to Step S406 is performed again.

FIG. 6 is a diagram of a read-out direction ROD and sampling points SP in a k-space ks and signal areas SA, various FOVs, a reconstruction region RR, stopbands SB, and cut-off positions CP corresponding to cutoff frequencies in an image space IS. As illustrated in FIG. 6, the read-out direction ROD passes through the center of the k-space ks and is parallel to a kx direction. UF in the image space IS denotes the user FOV set through the input interface 127. SF in the image space IS denotes an FOV in oversampling, that is, sampling defined by the sampling points SP disposed side by side. As illustrated in FIG. 6, the cut-off positions CP corresponding to the cutoff frequencies are positioned outside SF corresponding to the FOV in sampling. In other words, a passband PB of the low-pass filter 191 for MR signals is larger than SF corresponding to the FOV in sampling.

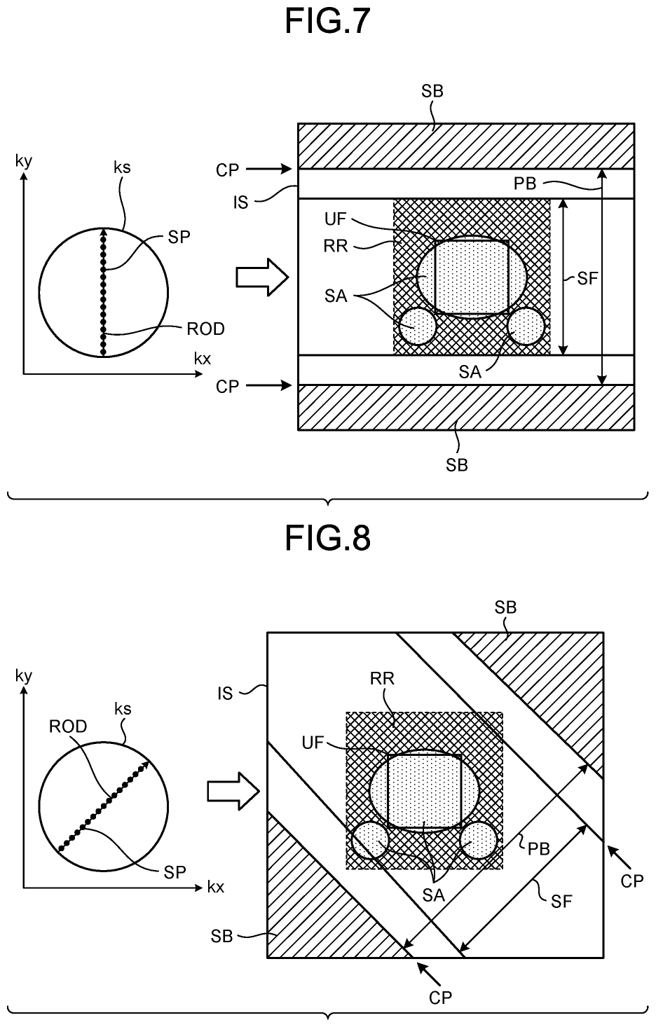

FIG. 7 is a diagram of the read-out direction ROD and the sampling points SP in the k-space ks and the signal areas SA, various FOVs, the reconstruction region RR, the stopbands SB, and the cut-off positions CP corresponding to the cutoff frequencies in the image space IS. FIG. 7 is different from FIG. 6 in that the read-out direction ROD in FIG. 7 passes through the center of the k-space ks and is parallel to a ky direction. As illustrated in FIG. 7, the cut-off positions CP corresponding to the cutoff frequencies are positioned outside SF corresponding to the FOV in sampling. In other words, the passband PB of the low-pass filter 191 for MR signals is larger than SF corresponding to the FOV in sampling.

FIG. 8 is a diagram of the read-out direction ROD and the sampling points SP in the k-space ks and the signal areas SA, various FOVs, the reconstruction region RR, the stopbands SB, and the cut-off positions CP corresponding to the cutoff frequencies in the image space IS. FIG. 8 is different from FIGS. 6 and 7 in that the read-out direction ROD in FIG. 8 passes through the center of the k-space ks and inclines at 45° with respect to the kx direction or the ky direction. As illustrated in FIG. 8, the cut-off positions CP corresponding to the cutoff frequencies are positioned outside SF corresponding to the FOV in sampling. In other words, the passband PB of the low-pass filter 191 for MR signals is larger than SF corresponding to the FOV in sampling. As illustrated in FIG. 8, the signal areas SA are included in the passband PB. As illustrated in FIG. 8, the passband PB of the low-pass filter is larger than the signal areas SA. Consequently, the total number of MR signals in all the read-out directions in the main scanning is uniform.

Step S408

The generation function 37 of the processing circuitry 131 generates a main scanning image based on MR data. The generation function 37, for example, generates the main scanning image using SENSE as expressed by the following expression.

$${argmin}_{x} [ {\sum }_{k} {‖ {F}_{k} Sx - {y}_{k} ‖}_{2}^{2} + R ( x ) ] \qquad ( 1 )$$

In the expression, x denotes data (main scanning image) in an image space in an expanded FOV, that is, an FOV in oversampling, Fₖ denotes Fourier transform in the k-th read-out direction, yₖ denotes MR data in the k-th read-out direction, S denotes a coil sensitivity matrix corresponding to all the coil sensitivity maps, and R(x) denotes a regularization term relating to the main scanning image x. If the coil sensitivity map is not used, S in the expression is omitted, and a formula corresponding to various assumptions relating to the main scanning image is incorporated in the regularization term R(x). The generation function 37 determines x so as to satisfy Expression (1), thereby generating the main scanning image.

The method for reconstructing the main scanning image by the generation function 37 is not limited to SENSE and may be compressed sensing (CS) or a reconstruction method for super resolution, for example. If the main scanning is performed by PROPELLER acquisition PRP or acquisition BL2 with two blades, for example, the generation function 37 can generate the main scanning image by a reconstruction method using generalized auto-calibrating partially parallel acquisition (GRAPPA).

The generation function 37 may generate the main scanning image using not only the coil sensitivity map but also frame correlation for video reconstruction as expressed by the following expression:

$${argmin}_{x} [ {\sum }_{k} {‖ {F}_{k} {Sx}_{i} - {y}_{i , k} ‖}_{2}^{2} + {\sum }_{j \neq l} {λ}_{i j} {\sum }_{k} {‖ {F}_{k} {S}_{k} {MC}_{i j} ( {x}_{i} ) - {y}_{j , k} ‖}_{2}^{2} + R ( x ) ] \qquad ( 2 )$$

In the expression, x₁ denotes data (main scanning image) in the image space of the i-th frame in an expanded FOV, that is, an FOV in oversampling, Fₖ denotes Fourier transform in the k-th read-out direction, y_{i,k} denotes MR data in the k-th read-out direction in the i-th frame, S denotes a coil sensitivity matrix corresponding to all the coil sensitivity maps, the second term indicates frame correlation by motion, that is, an influence by motion compensation (MC), and R(x) denotes a regularization term in the time direction relating to the main scanning image x. The generation function 37 determines x so as to satisfy Expression (2), thereby generating the main scanning image.

As described above, the MRI apparatus 100 according to the first embodiment acquires a plurality of MR signals corresponding to a plurality of read-out directions including a first read-out direction and a second read-out direction intersecting the first read-out direction. The MRI apparatus 100 specifies the signal area SA relating to generation of the MR signals in a pre-scanning image (locator image LI) of the subject P. The MRI apparatus 100 sets a cutoff frequency defining the passband PB for the MR signals based on the specified signal area SA. The MRI apparatus 100 filters the MR signals acquired by scanning (main scanning) performed on the subject P in the read-out directions using the set cutoff frequency. The MRI apparatus 100 generates an MR image (main scanning image) based on MR data generated by A/D conversion performed on the MR signals output from the low-pass filter 191.

The MRI apparatus 100 specifies the signal area SA by detecting an image of the subject P in the pre-scanning image (locator image LI) or by specifying the area in the pre-scanning image (locator image LI) by the user. The MRI apparatus 100 sets a cutoff frequency further using the field of view FOV and the intensity of the gradient magnetic field in the main scanning.

Consequently, the MRI apparatus 100 according to the first embodiment can set the cutoff frequency so as to include the signal area SA relating to generation of the MR signals. The MRI apparatus 100 can set the cutoff frequencies for the respective read-out directions. Consequently, the MRI apparatus 100 can set the cutoff frequency such that the number of MR signals corresponding to the read-out directions is uniform regardless of the read-out directions.

In the MRI apparatus 100 according to the first embodiment, the MR signals generated in the signal area SA are not filtered by the low-pass filter 191 as illustrated in FIGS. 6 to 8 in scanning performed in varying read-out directions. In other words, the MR signals are not cut-off (suppressed) depending on the read-out directions. As a result, the MRI apparatus 100 can acquire consistent data on the k-space. Consequently, the MRI apparatus 100 can acquire a high-quality image with fewer streaks.

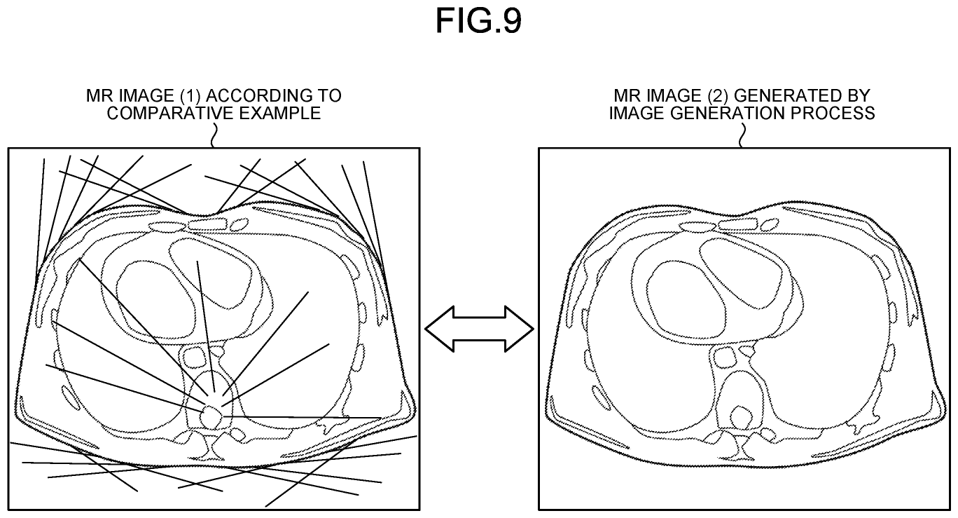

FIG. 9 is a diagram of an example of an MR image (1) obtained when the cutoff frequency of the low-pass filter is a tentative cut-off frequency according to a comparative example and an MR image (2) generated by image generation process according to the present embodiment. As illustrated in FIG. 9, the MR image (2) generated by image generation process has fewer streak artifacts or the like and has higher image quality than the MR image (1) obtained when the cutoff frequency is the tentative cut-off frequency. Consequently, the MRI apparatus 100 according to the present embodiment can generate an MR image having higher image quality in the main scanning.

### Second Embodiment

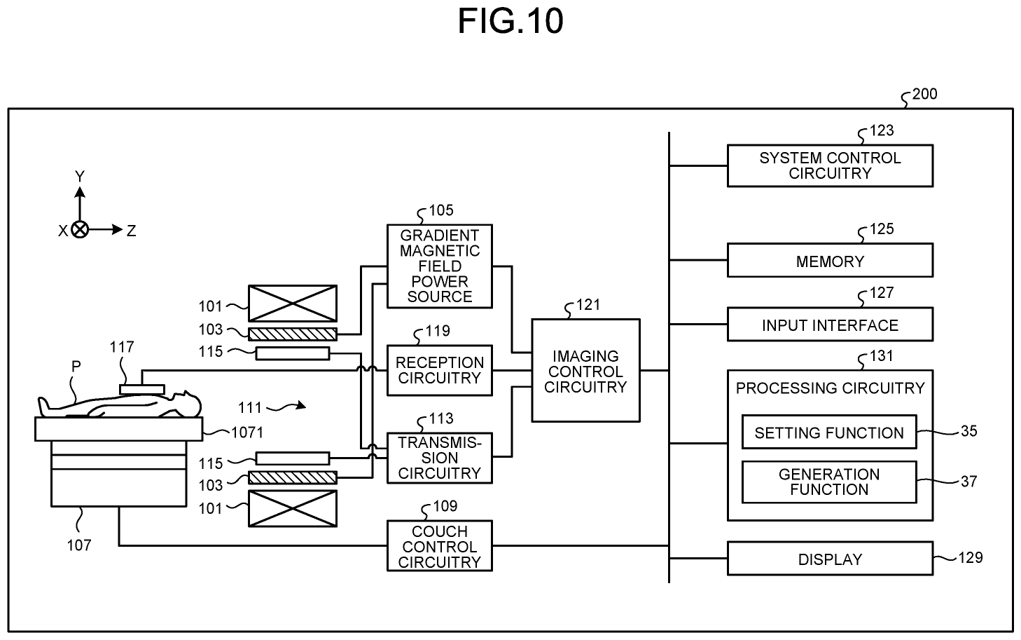

FIG. 10 is a block diagram of an example of an MRI apparatus 200 according to a second embodiment. The MRI apparatus 200 according to the second embodiment is different from the MRI apparatus 100 according to the first embodiment in that it does not include the specification function 33. The following describes the processing at Step S403 and Step S405 different from the processing according to the first embodiment in image generation process according to the present embodiment.

Image Generation Process Step S403

The setting function 35 of the processing circuitry 131 sets cutoff frequencies defining the passband PB for a plurality of MR signals corresponding to a plurality of read-out directions for the respective read-out directions based on the user FOV in the main scanning performed on the subject P in the read-out directions. While the first embodiment sets a uniform cutoff frequency for all the read-out directions in the main scanning, the second embodiment sets the cutoff frequencies for the respective read-out directions.

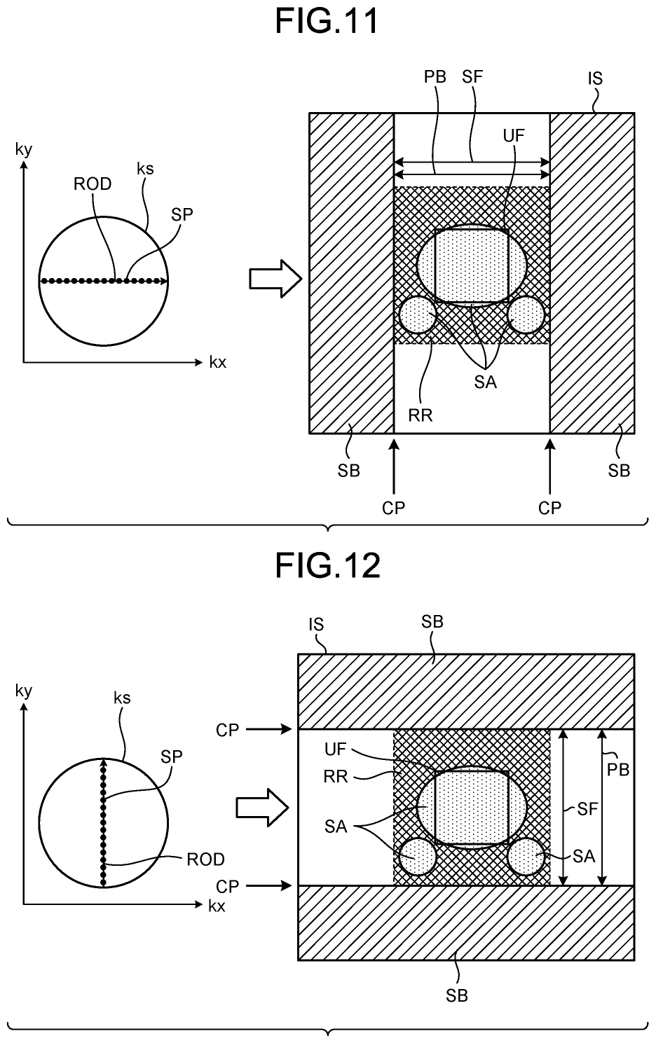

The setting function 35, for example, sets the cutoff frequency based on an angle θ (radian) of the read-out direction with respect to the kx direction. The set cutoff frequency is output to the low-pass filter 191 in a manner associated with the read-out direction. Specifically, when 0≤θ≤π/4, 3π/4≤θ≤5π/4, and 7π/4≤θ≤2π are satisfied, the setting function 35 sets a value obtained by multiplying the tentative cut-off frequency by 1/|cos θ| as the cutoff frequency. When π/4≤θ≤3π4 and 5π/4≤θ≤7π/4 are satisfied, the setting function 35 sets a value obtained by multiplying the tentative cut-off frequency by 1/|sin θ| as the cutoff frequency. If the cutoff frequency is set as described above, the image space IS illustrated in FIG. 6 has the configuration illustrated in FIG. 11 when θ=0 and θ=π are satisfied. The image space IS illustrated in FIG. 7 has the configuration illustrated in FIG. 12 when θ=π/2 and θ=3π/2 are satisfied. When θ=π/4 and θ=5π/4 are satisfied, the image space IS according to the present embodiment also has the configuration illustrated in FIG. 8.

Step S405

The low-pass filter 191 receives the cutoff frequency associated with the read-out direction in the radial acquisition performed at Step S404. The low-pass filter 191 filters the MR signals resulting from wave detection (e.g., differential signals between the received MR signals and a carrier frequency) using the cutoff frequency associated with the read-out direction. The MR signals resulting from filtering are output to the A/D converter 193.

FIG. 11 is a diagram of the read-out direction ROD and the sampling points SP in the k-space ks and the signal areas SA, various FOVs, the reconstruction region RR, the stopbands SB, and the cut-off positions CP corresponding to the cutoff frequencies in the image space IS. As illustrated in FIG. 11, the read-out direction ROD passes through the center of the k-space ks and is parallel to the kx direction. UF in the image space IS denotes the user FOV set through the input interface 127. SF in the image space IS denotes an FOV in oversampling, that is, sampling defined by the sampling points SP disposed side by side. As illustrated in FIG. 11, the cut-off positions CP corresponding to the cutoff frequencies are at the same position as that of the ends of SF corresponding to the FOV in sampling. In other words, the passband PB of the low-pass filter 191 for MR signals is equal to SF corresponding to the FOV in sampling.

FIG. 12 is a diagram of the read-out direction ROD and the sampling points SP in the k-space ks and the signal areas SA, various FOVs, the reconstruction region RR, the stopbands SB, and the cut-off positions CP corresponding to the cutoff frequencies in the image space IS. FIG. 12 is different from FIG. 11 in that the read-out direction ROD in FIG. 12 passes through the center of the k-space ks and is parallel to the ky direction. As illustrated in FIG. 12, the cut-off positions CP corresponding to the cutoff frequencies are at the same position as that of the ends of SF corresponding to the FOV in sampling. In other words, the passband PB of the low-pass filter 191 for MR signals is equal to SF corresponding to the FOV in sampling.

If the technical ideas according to the second embodiment are applied to the first embodiment as a modification of the second embodiment, the MRI apparatus 100 includes the specification function 33 as illustrated in FIG. 1. The specification function 33 of the processing circuitry 131 specifies the farthest positions in the respective read-out directions. Subsequently, the setting function 35 of the processing circuitry 131 may set the farthest frequencies corresponding to the farthest positions or frequencies obtained by adding a predetermined margin frequency to the farthest frequencies as the cutoff frequencies for the respective read-out directions. The cutoff frequency may be higher or lower than the tentative cut-off frequency as illustrated in FIG. 8.

As described above, the MRI apparatus 200 according to the second embodiment acquires a plurality of MR signals corresponding to a plurality of read-out directions including a first read-out direction and a second read-out direction intersecting the first read-out direction. The MRI apparatus 200 sets cutoff frequencies defining the passband PB for the MR signals for the respective read-out directions based on the user FOV in the main scanning performed on the subject P in the read-out directions. The MRI apparatus 200 filters the MR signals acquired by the main scanning performed in the read-out directions using the cutoff frequencies set for the respective read-out directions. The MRI apparatus 200 generates an MR image based on MR data generated by A/D conversion performed on the MR signals output from the low-pass filter 191.

Consequently, the MRI apparatus 200 according to the present embodiment can set the cutoff frequencies including the signal area SA relating to generation of the MR signals for the respective read-out directions. In other words, the MRI apparatus 200 can set the cutoff frequencies such that the number of MR signals corresponding to the read-out directions is uniform regardless of the read-out directions for the respective read-out directions. The advantageous effects according to the present embodiment are not explained herein because they are the same as those according to the first embodiment.

### Third Embodiment

The configuration of the MRI apparatus according to a third embodiment is the same as that of the MRI apparatus 200 according to the second embodiment. The following describes the processing at Step S403 different from the processing according to the first embodiment in image generation process according to the present embodiment.

Image Generation Process

Step S403

The setting function 35 of the processing circuitry 131 multiplies a frequency (tentative cut-off frequency) determined based on the user FOV in the main scanning performed on the subject P in a plurality of read-out directions and the intensity of the gradient magnetic field in the main scanning by a constant. The setting function 35 thus sets a cutoff frequency defining the passband PB for a plurality of magnetic resonance signals corresponding to the read-out directions. The setting function 35, for example, sets the constant based on the sequence of the main scanning.

Specifically, if the sequence of the main scanning is performed by two-dimensional imaging, such as two-dimensional radial acquisition R2D, three-dimensional radial acquisition (stack-of-stars) Sos, PROPELLER acquisition PRP, or acquisition BL2 with two blades illustrated in FIG. 3, the setting function 35 sets the constant to 2^{1/2} (e.g., 1.41 when the number of significant digits is 3). The setting function 35 multiplies the tentative cut-off frequency by 1.41, thereby setting the cutoff frequency. If the sequence of the main scanning is performed by three-dimensional imaging, such as koosh-ball KB illustrated in FIG. 3, the setting function 35 sets the constant to 3^{1/2} (e.g., 1.73 when the number of significant digits is 3). The setting function 35 multiplies the tentative cut-off frequency by 1.73, thereby setting the cutoff frequency.

The MRI apparatus 200 according to the third embodiment multiplies a tentative cut-off frequency determined based on the user FOV in the main scanning performed on the subject P in a plurality of read-out directions and the intensity of the gradient magnetic field in the main scanning by a constant, thereby setting a cutoff frequency defining the passband PB for MR signals. The MRI apparatus 200 filters the MR signals acquired by the main scanning performed in the read-out directions using the set cutoff frequency. The MRI apparatus 200 generates a magnetic resonance image based on MR data generated by A/D conversion performed on the MR signals output from the low-pass filter 191. The MRI apparatus 200 according to the third embodiment sets the constant based on the sequence of the main scanning.

Consequently, the MRI apparatus 200 according to the present embodiment can set the cutoff frequency in a simpler manner based on the sequence of the main scanning. The advantageous effects according to the present embodiment are not explained herein because they are the same as those according to the first embodiment.

To implement the technical ideas according to the first embodiment by an image generation method, the image generation method includes: specifying the signal area SA relating to generation of a plurality of MR signals in a pre-scanning image (locator image LI) of the subject P in a plurality of read-out directions including a first read-out direction and a second read-out direction intersecting the first read-out direction; setting a cutoff frequency defining the passband PB for the MR signals based on the specified signal area SA; filtering the MR signals acquired by main scanning performed on the subject P in the read-out directions with the low-pass filter 191 using the set cutoff frequency; generating MR data by A/D conversion performed on the MR signals output from the low-pass filter 191; and generating an MR image based on the generated MR data. The process and the advantageous effects of the image generation process performed by the present image generation method are not explained herein because they are the same as those according to the first embodiment.

At least one of the embodiments and the like described above can generate a magnetic resonance image having higher image quality. In other words, at least one of the embodiments and the like can acquire consistent data on the k-space in scanning performed in varying read-out directions. Consequently, at least one of the embodiments and the like can acquire a high-quality MR image with fewer streaks.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus configured to acquire a plurality of magnetic resonance signals corresponding to a plurality of read-out directions including a first read-out direction and a second read-out direction intersecting the first read-out direction, the magnetic resonance imaging apparatus comprising:
processing circuitry configured to
specify a signal area relating to generation of the magnetic resonance signals in a subject, and
set a cutoff frequency defining a passband for the magnetic resonance signals based on the signal area; and
a low-pass filter configured to filter the magnetic resonance signals acquired by scanning performed on the subject in the read-out directions using the cutoff frequency, wherein
the processing circuitry generates a magnetic resonance image based on magnetic resonance data generated by A/D conversion performed on the magnetic resonance signals output from the low-pass filter.

2. The magnetic resonance imaging apparatus according to claim 1, wherein the processing circuitry sets the cutoff frequency further using a field of view in the scanning and intensity of a gradient magnetic field in the scanning.

3. The magnetic resonance imaging apparatus according to claim 1, wherein the processing circuitry specifies the signal area by detecting an image of the subject or specification by a user.

4. The magnetic resonance imaging apparatus according to claim 1, wherein the processing circuitry sets the cutoff frequencies for the respective read-out directions based on the signal area.

5. A magnetic resonance imaging apparatus configured to acquire a plurality of magnetic resonance signals corresponding to a plurality of read-out directions including a first read-out direction and a second read-out direction intersecting the first read-out direction, the magnetic resonance imaging apparatus comprising:
processing circuitry configured to set a cutoff frequency defining a passband for the magnetic resonance signals for the respective read-out directions based on a field of view in scanning performed on a subject in the read-out directions; and
a low-pass filter configured to filter the magnetic resonance signals acquired by the scanning performed in the read-out directions using the cutoff frequencies, wherein the processing circuitry generates a magnetic resonance image based on magnetic resonance data generated by A/D conversion performed on the magnetic resonance signals output from the low-pass filter.

6. A magnetic resonance imaging apparatus configured to acquire a plurality of magnetic resonance signals corresponding to a plurality of read-out directions including a first read-out direction and a second read-out direction intersecting the first read-out direction, the magnetic resonance imaging apparatus comprising:
processing circuitry configured to multiply, by a constant, a frequency determined based on a field of view in scanning performed on a subject in the read-out directions and intensity of a gradient magnetic field in the scanning, thereby setting a cutoff frequency defining a passband for the magnetic resonance signals; and
a low-pass filter configured to filter the magnetic resonance signals acquired by the scanning performed in the read-out directions using the cutoff frequency, wherein
the processing circuitry generates a magnetic resonance image based on magnetic resonance data generated by A/D conversion performed on the magnetic resonance signals output from the low-pass filter.

7. The magnetic resonance imaging apparatus according to claim 6, wherein the processing circuitry sets the constant based on a sequence of the scanning.

8. The magnetic resonance imaging apparatus according to claim 1, wherein the processing circuitry sets the cutoff frequency such that number of magnetic resonance signals is uniform regardless of the read-out directions.

9. The magnetic resonance imaging apparatus according to claim 1, wherein the processing circuitry sets the cutoff frequency so as to include the signal area relating to generation of the magnetic resonance signals.

10. An image generation method comprising:
specifying a signal area relating to generation of magnetic resonance signals in a subject in a plurality of read-out directions including a first read-out direction and a second read-out direction intersecting the first read-out direction;
setting a cutoff frequency defining a passband for the magnetic resonance signals based on the signal area;
filtering the magnetic resonance signals acquired by scanning performed on the subject in the read-out directions with a low-pass filter using the cutoff frequency;
generating magnetic resonance data by A/D conversion performed on the magnetic resonance signals output from the low-pass filter; and
generating a magnetic resonance image based on the magnetic resonance data.
